(19) United States
(12) Patent Application Publication
(10) Pub. No.: US 2024/0397630 A1
(43) Pub. Date: Nov. 28, 2024

(54) PROCESS FOR PRODUCING AN INTERCONNECT DEVICE FOR ELECTRONIC AND/OR MECHATRONIC COMPONENTS AND INTERCONNECT DEVICE

(71) Applicant: FRAUNHOFER-GESELLSCHAFT ZUR FÖRDERUNG DER ANGEWANDTEN FORSCHUNG E.V., München (DE)

(72) Inventor: Friedrich PROES, Hamburg (DE)

(21) Appl. No.: 18/274,544

(22) PCT Filed: Jan. 19, 2022
(86) PCT No.: PCT/DE2022/100051

§ 371 Date: Jul. 11, 2024

(30) Foreign Application Priority Data
Jan. 30, 2021 (DE) 102021102175.8

(51) Int. Cl. H05K 3/00; B33Y 40/20; B33Y 70/10; B33Y 80/00; H05K 1/03

(52) U.S. Cl. CPC H05K 3/0011; B33Y 40/20; B33Y 70/10; B33Y 80/00; H05K 1/0353; H05K 2203/107

(57) ABSTRACT

The invention relates to a method for manufacturing a circuit carrier (1) for electronic and/or mechatronic components, a circuit carrier for electronic and/or mechatronic components and a circuit. In particular, the invention relates to a method for producing a circuit carrier (1) for electronic and/or mechatronic components, comprising the steps of producing a base body (2) using an additive manufacturing method, the base body (2) having or consisting of a plastic material (8) with metal particles (10), applying a smoothing means which dissolves the plastic material (8) to a base body surface (3) of the base body (2) so that the base body surface (3) is substantially free of metal particles (10), and producing at least one conductor path (12, 18) on the base body surface (3).

The invention relates to a method for manufacturing a circuit carrier for electronic and/or mechatronic components, a circuit carrier for electronic and/or mechatronic components and a circuit.

Circuit carriers, in particular three-dimensional circuit carriers, are known in principle and are also referred to as molded interconnect devices (3D-MID). Such circuit carriers are usually manufactured by injection molding. For manufacturing using the injection molding process, a mold is provided with a cavity that is essentially a negative of the three-dimensional circuit carrier.

The injection molding process is characterized by cost-intensive operating resources, especially by the mold, and high operating costs for the injection molding machines. For this reason, the injection molding process is usually only economically viable for quantities greater than 10,000 units, and regularly only for quantities greater than 50,000 units. Once the injection mold has been produced, design changes to the circuit carrier are only possible to a limited extent or not at all, as this requires time-consuming and cost-intensive modifications to the injection mold or the injection molding cassette.

As a result, product development of new circuit carriers is time-consuming, as prototyping is not possible with the series tool. In addition, individualized mass production of circuit carriers, in particular three-dimensional circuit carriers, cannot be reproduced with the injection molding process, or only to a limited extent.

As an alternative to injection molding, additive manufacturing processes are increasingly being used for suitable components. In contrast to injection molding, additive manufacturing processes generally have lower fixed costs, which means that the unit costs are essentially independent of the number of units. As a result, additive manufacturing processes enable cost-effective production of individual parts, pilot series and small batches, in contrast to the use of injection molding processes. In addition, additive manufacturing processes enable individualized mass production. Furthermore, additive manufacturing processes can enable high component complexities and high variant folds.

However, the possible applications of additive manufacturing processes must be weighed up individually for the component to be manufactured. Additive manufacturing processes are generally characterized by long process times. Furthermore, additively manufactured components have physically determined component properties, some of which are undesirable. For example, a stair-step structure is usually produced on curved or sloping surfaces, which is caused by the layered structure.

Furthermore, components manufactured using additive manufacturing processes are usually characterized by a rough surface, which often does not meet the requirements for circuit carriers, especially three-dimensional circuit carriers. Grinding manufacturing processes for smoothing the surface are not suitable for many additively manufactured components because grinding processing is not possible or only possible to a limited extent. For example, small component structures are also removed, angled component areas cannot be reached by the grinding treatment and, in many cases, the material used is tough, smeared and clogs the grinding paper or body. In addition, the free-form surfaces that are frequently produced can only be machined by grinding at great expense.

Chemical smoothing processes are known to be unsuitable for filled plastics. In the case of fillers such as glass beads, fibers, carbon fibers or aluminum particles, a physical impediment to smoothing occurs due to the presence of the fillers. Furthermore, with more reactive fillers, such as copper, a reaction of the smoothing medium with the metal is to be expected, which may contaminate the surface with the reaction products and render it unusable.

In addition, it has been shown that when conductor paths are applied to a circuit carrier produced by an additive manufacturing process, often only fairly coarse conductor path detailing is possible. For example, only a minimum pitch dimension of 1000 μm is possible, with, for example, a minimum trace spacing of 500 μm and a minimum trace width of 500 μm. However, many applications require smaller trace widths and pitch dimensions of 100-150 μm.

Conventional approaches to manufacturing circuit carriers include the laser direct structuring method, also known as the LDS method, and two-component injection molding. These methods are based on injection molding as the primary forming method and have chemical metallization as the conductor path forming method in common in the subsequent process chain. The methods differ in the principle of activation. In the LDS method, activation is by laser beam. In two-component injection molding, two different plastics are used, one of which is metallizable and the other non-metallizable. Neither method is economical for small batch sizes.

Additively manufactured components generally have higher roughness, which causes the actual contour of the conductor paths to deviate more from the nominal contour. In addition, the higher roughness leads to foreign metallization. As a result, additively manufactured circuit carriers generally require larger distances between the individual conductor paths than injection-molded circuit carriers.

The quality of the conductor paths is lower than that of such conductor paths on injection-molded circuit carriers. The larger distances between the individual conductor paths mean that the circuit carriers have to be made larger and/or are unsuitable for certain applications and/or are incompatible with certain electronic components.

WO 03/005784A2 describes conductor track structures on a non-conductive carrier material which consist of metal nuclei and a metallization subsequently applied to them, the metal nuclei having been produced by breaking up non-conductive metal compounds contained in the carrier material in a finely distributed manner by electromagnetic radiation. In particular, the LDS process chain is described. U.S. Pat. No. 10,119,021 B2 also discloses the LDS process chain, wherein a coating of an organometallic compound is applied to the component.

No method is known from the prior art that enables the additive production of a circuit carrier, in particular by means of a powder bed-based process, on which conductor paths can be arranged with a high level of detail.

It is therefore an object of the present invention to provide a method for manufacturing a circuit carrier for electronic and/or mechatronic components, a circuit carrier and a circuit which reduce or eliminate one or more of the disadvantages mentioned. In particular, it is an object of the invention to provide a solution that enables economical production of a circuit carrier with conductor paths in small quantities, in particular smaller than 10,000, preferably smaller than 1,000, in particular smaller than 10.

This task is solved with a method for producing a circuit carrier for electronic and/or mechatronic components and a circuit carrier for electronic and/or mechatronic components with the features of the independent patent claims. Further advantageous embodiments of the method and of the circuit carrier are given in the respective dependent patent claims. The features listed individually in the patent claims can be combined with one another in any technologically useful manner and can be supplemented by further features from the description, wherein further embodiments of the invention are shown.

The method comprises the step of: producing a base body using an additive manufacturing process, wherein the base body comprises or consists of a plastic material with metal particles. Preferably, the circuit carrier and/or the base body is or are configured in three dimensions. In particular, it is preferred that the circuit carrier and/or the base body have at least one free-form surface.

It is preferred that the base body is made from a base material, wherein the base material comprises or consists of the plastic material and the metal particles. For example, the base material may be in powder form. It is preferred that a concentration of the metal particles in the base material is between 0.1 and 20% by weight. It is further preferred that the concentration is less than 10% by weight, less than 5% by weight, in particular between 1 and 3% by weight.

It is preferred that the metal particles are distributed substantially homogeneously in the plastic material. A base body produced in such a manner has a plastic material in which the metal particles are substantially homogeneously distributed.

Due to the distribution of the metal particles in the plastic material, the metal particles are also located on the base body surface of the base body. Accordingly, the metal particles are visible and accessible from the outside.

The inventor has found that these externally accessible metal particles are responsible for tramp metallization in the generation of conductor paths. In particular, it has been found that due to these metal particles, the detail of the conductor paths is limited. It was further found that the quality of the circuit carrier is reduced due to reduced surface resistances and the consequent increased risk of short circuits, as well as favoring leakage currents.

Surprisingly, the inventor has found that tramp metallization can be avoided by applying a smoothing means that dissolves the plastic material to the base body surface of the base body. By applying the smoothing means to the base body surface, the plastic material is dissolved close to the surface and the metal particles are enclosed and/or coated by the plastic material. At the same time, the quality of the surface is not negatively affected by chemical reaction products, as was to be feared, but on the contrary the surface quality and thus the quality of the entire component is improved, so that the components can be used for a wide range of new applications.

One reason for this effect is that the base body surface is dissolved by the smoothing means and changes to a melt-like state in which the dissolved plastic is viscous and deformable. The surface tension of the melt-like plastic material on the surface of the base body, causes the surface to smooth out, thus reducing the surface roughness and trapping metal particles in the plastic. Another advantage of this smoothing of the base body surface is that aesthetic and/or haptic requirements for the circuit carrier are met.

The smoothing means is preferably configured such that it volatilizes under predefined boundary conditions, in particular in a predefined pressure range and/or in a predefined temperature range. Hardening of the dissolved plastic material takes place in particular as soon as the smoothing means has volatilized. Typically, this occurs during aeration of the base body. Since the smoothing means volatilizes over a longer period of time, this is preferably done in a controlled manner. The dissolved base body surface is soft during the time until curing and can lead to unintentional deformation if the base body is not handled properly. It is therefore preferable to leave the base body in the vapor deposition chamber or main chamber, for example, until it has cured. Defined aeration of the base body surface can accelerate the curing process.

The smoothing means is preferably configured such that it dissolves the base body to a depth of more than 10 μm, preferably more than 20 μm, and at most to a depth of 500 μm, preferably 200 μm.

Subsequently, at least one conductor path is generated on the base body surface. The conductor paths can be generated by different methods, as will be explained in more detail below.

Essentially free of metal particles means in particular that the concentration of metal particles at the surface is more than 50%, more than 75%, more than 80%, more than 90% and/or more than 95% lower than in the rest of the base body, in particular in areas remote from the surface.

In a preferred embodiment of the method, it is provided that the smoothing means dissolving the plastic material is applied to the base body surface in such a way that the base body surface has an average roughness depth of less than 50 μm, less than 40 μm, less than 30 μm and/or less than 20 μm.

A further preferred embodiment of the method is characterized in that the additive manufacturing process is selective laser melting. Selective laser melting is an additive manufacturing method that belongs to the group of beam melting methods and to the group of powder bed-based methods. In selective laser melting, the material to be processed is deposited in powder form in a thin layer on a base plate. Presently, the material comprises the plastic material and the metal particles.

The powdered material is locally remelted by means of laser radiation and forms a solid material layer after solidification. Subsequently, the base plate is lowered by the amount of a layer thickness and powder is applied again. This cycle is repeated until all layers have been remelted. Typical layer thicknesses are between 60 μm and 200 μm.

Furthermore, it is preferred that the additive manufacturing process is or comprises an absorption printing process and/or a fused layer process. The absorption printing process is also referred to as Multi Jet Fusion (MJF) and High Speed Sintering (HSS). The fused layer process is also referred to as fused deposition modeling (FDM) and fused filament fabrication (FFF).

In another preferred embodiment of the method, generating at least one conductor path comprises the step of: Laser activation of one, two or more conductor path sections on the base body surface in which one, two or more conductor paths are to be arranged.

In the laser activation step, the activation is performed by laser energy. A physical and/or physico-chemical reaction generates metallic nuclei, which can serve as a starting point for growth of a conductor track material during subsequent metallization. In addition to activation, the laser energy is used to configure a microrough surface to which the conductor track material to be applied adheres during metallization in an advantageous manner.

Furthermore, it is preferred that a pulsed laser is used for the laser activation. In particular, it is preferred that a solid-state laser, especially a Nd:YAG laser, is used. The emitted laser beam, in particular the emitted infrared radiation, further preferably has a wavelength of 1064 nm. It is preferred that the frequency of the laser is between 1-100 kHz. Preferably, the scanning speed is between 1-5000 mm/s. The nominal laser power is preferably between 1 W and 10 W, further preferably between 2 W and 5 W, most preferably between 3 W and 4 W, for example 3.5 W. Furthermore, it is preferred that the pulse length is between 1-100 μs, preferably between 3-50 μs. Preferably, the focal diameter can be between 30 μm and 100 μm. The focal length is preferably between 50 mm and 200 mm.

A further preferred embodiment of the method is characterized in that the generation of at least one conductor path comprises the step: Metallization, in particular selective metallization, of the conductor path sections with a conductor path material forming the conductor path or conductor paths. The conductor track material is preferably copper.

Metallization is generally defined as the coating of an object with a metal layer. In particular, metallization is to be understood as a thin-film process by which thin-film conductor paths can be produced. Metallization of plastics to form conductor paths is often performed in electroless copper baths. Typically, this achieves a thickness of 6 μm/hour to 12 μm/hour. This can be followed by an additional electroless application of nickel and/or a thin gold layer.

In a further preferred embodiment, it is provided that the applying is or comprises steaming with the smoothing means, wherein preferably the steaming is carried out with a predetermined steaming pressure and/or a predetermined temperature.

The steaming can be carried out, for example, with a multi-chamber system. In a main chamber, the base body is arranged, for example suspended from a hook. In a secondary chamber there is a smoothing means evaporation unit, in which the smoothing means is evaporated. From the secondary chamber, the evaporated smoothing means passes into the main chamber and thus to the base body. The smoothing agent vapor condenses on the base body. As a result, the surface is loosened by means of the smoothing means. This is usually followed by aeration and removal of the base body. The smoothing of plastic part produced by an additive manufacturing process is described, for example, in WO2020/049186A1 or WO2020/007444A1. The base body can be steamed with the smoothing means for 20 minutes, for example. Depending on the size and geometry of the base body as well as further boundary conditions, this time may be shorter or longer.

In a further preferred embodiment, it is provided that the vaporization pressure is between 0 bar and 1 bar, preferably 2 bar. In particular, it is preferred that the base body is in a vacuum at the start of, during and/or after the steaming process. Vacuum refers in particular to the state of the gas or gases in the space in which the basic body is located before, during and/or after vapor deposition, at a pressure which is significantly lower than atmospheric pressure under normal conditions.

For example, a rough vacuum, a fine vacuum, a high vacuum, or an ultra-high vacuum can be set.

Furthermore, it is preferred that the predetermined temperature is between 100° C. and 120° C., in particular between 105° C. and 110° C. In particular, it is preferred that a temperature of the base body is set during vapor deposition that is below a temperature of the vaporized smoothing means so that the smoothing means condenses on the base body.

In a further preferred embodiment of the method, it is provided that the smoothing means is an etchant. For example, the etchant may be formic acid. Furthermore, it may be preferred that the smoothing means is an alcohol. In particular, it is preferred that benzyl alcohol is used.

It is further preferred that the smoothing means is acetaldehyde, acetamide, acetone, acetonitrile, acetophenone, acetylene, aliphatic hydrocarbons, in particular cyclohexane, cyclohexene, diisobutylene, hexane, octane, n-pentane and terpinene, alcohols, in particular butylene glycol, butanol, ethanol, ethylene glycol, methanol, allyl alcohol, n-propanol and isopropanol, amyl acetate, aniline, anisole, gasoline, benzaldehyde, benzene, chlorobenzene, dioxane, dimethylamide, dimethylformamide, diethyl ether, dimethylformamide, dimethyl sulfide, dimethyl sulfoxide, ethylbenzene, ethyl acetate, formaldehyde, formamide, furfurol, halocarbons, especially chlorobromomethane, chloroform, ethylene chloride, methylene chloride, perchloroethylene, tetrachloromethane, trichloroethane and trichloroethylene, menthone, methyl tert-butyl ether, methyl ethylene ketone, nitrobenzene, phenols, phenylethyl alcohol, propanol, pyridine, styrene, tetrahydrofuran, tetrahydronaphthalene, toluene, triethanolamine, or comprises combinations of any one or more thereof.

Preferably, the metal particles are configured to be electrically conductive. In addition, it is preferred that the metal particles are in powder form. The metal particles may be present as elemental metal and/or in the form of metal compounds. For the present application, metal compounds are, for example, spinels, in particular CuCrO, CuMoO and/or CuCrMnO spinels. Furthermore, the metal compounds may be in the form of copper salts, oxides and/or organic metal complexes. The metal particles are configured in particular such that they have as little or no influence as possible on the additive manufacturing process.

In a further preferred embodiment of the method, it is provided that the metal particles are or comprise copper particles and/or aluminum particles and/or nickel particles. In particular, it is preferred that the metal particles, in particular the copper particles, are present in substantially pure form, i.e., as elemental copper powder. Furthermore, it is preferred that the metal particles, in particular the copper particles, have a particle size of less than 30 μm, less than 20 μm, in particular between 5 μm and 15 μm.

In a further preferred embodiment, it is provided that the plastic material is configured thermoplastically. Furthermore, it may be preferred that the plastic material is or comprises a polyamide and/or thermoplastic polyurethane. Preferably, the polyamide is a polyamide 12, also referred to as PA 12, poly-laurylactam or nylon-12. Furthermore, polyamide 11, also referred to as PA11, and thermoplastic polyurethane, also referred to as TPU, are preferred.

The circuit carrier for electronic and/or mechatronic components is preferably manufactured by a method according to one of the embodiments described in the preceding. The circuit carrier comprises a base body produced by an additive manufacturing process, comprising a plastic material with metal particles. The base body has a base body surface that is substantially free of metal particles. Furthermore, the circuit carrier comprises at least one conductor path.

In a preferred embodiment of the circuit carrier, it is provided that the base body surface has an average roughness depth of less than 50 μm, less than 40 μm, less than 30 μm and/or less than 20 μm.

Furthermore, it is preferred that the metal particles are or comprise copper particles, and/or the metal particles, in particular the copper particles, have a particle size of less than 30 μm, less than 20 μm, in particular between 5 μm and 15 μm.

A further preferred further embodiment of the circuit carrier provides that the plastic material is configured thermoplastically. In particular, it is preferred that the plastic material is or comprises a polyamide and/or thermoplastic polyurethane.

According to a further aspect, the above-mentioned task is solved by a circuit comprising a circuit carrier according to one of the embodiments mentioned in the foregoing and at least one circuit component. The circuit component may be, for example, an electronic and/or mechatronic component.

For further advantages, embodiment variants and embodiment details of the circuit carrier and the circuit as well as their possible further embodiments, reference is also made to the previously given description regarding the corresponding features and further embodiments of the method.

Preferred embodiments are explained by way of example with reference to the accompanying figures. They show:

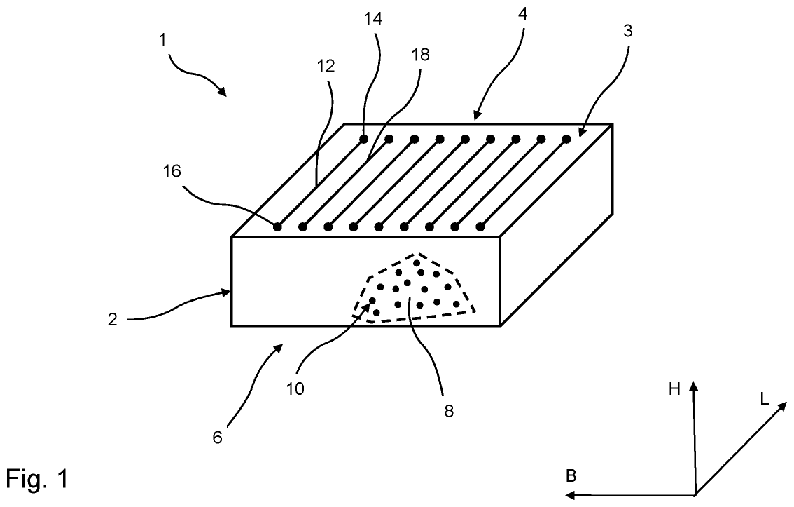

FIG. 1: a schematic, three-dimensional view of an exemplary embodiment of a circuit carrier;

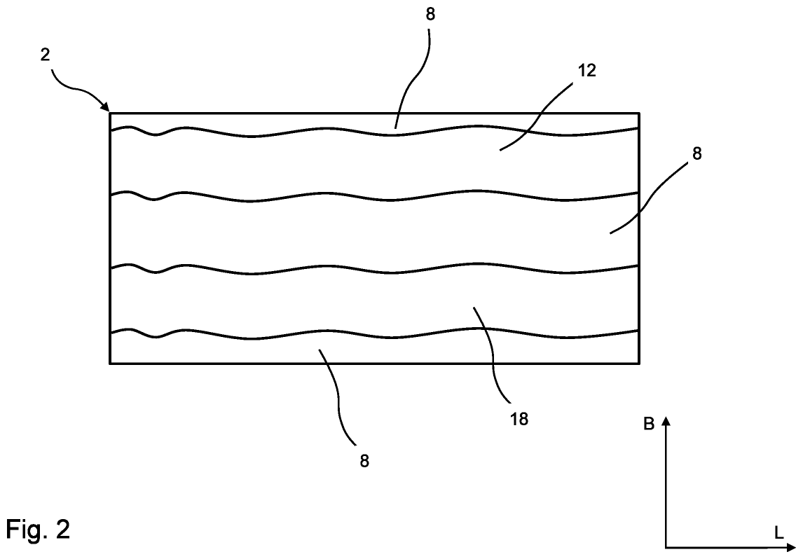

FIG. 2: a schematic, two-dimensional detailed view of the circuit carrier shown in FIG. 1;

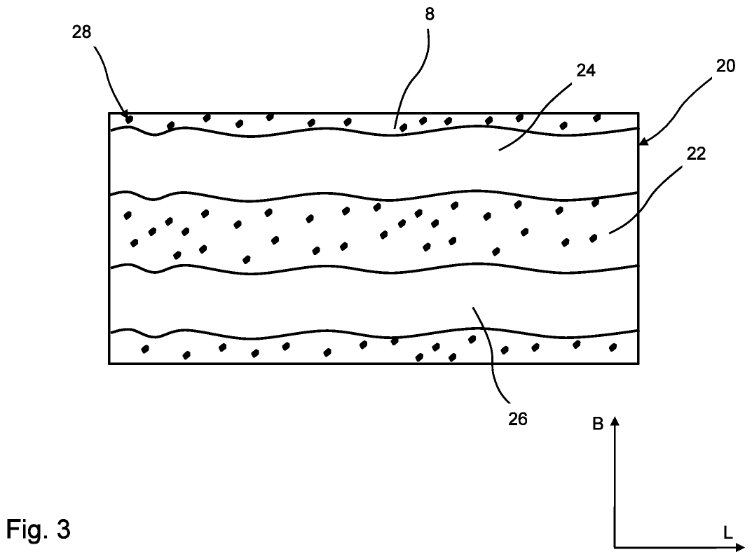

FIG. 3: a schematic, two-dimensional detailed view of a circuit carrier without applying a smoothing means to the surface of the base body to dissolve the plastic material;

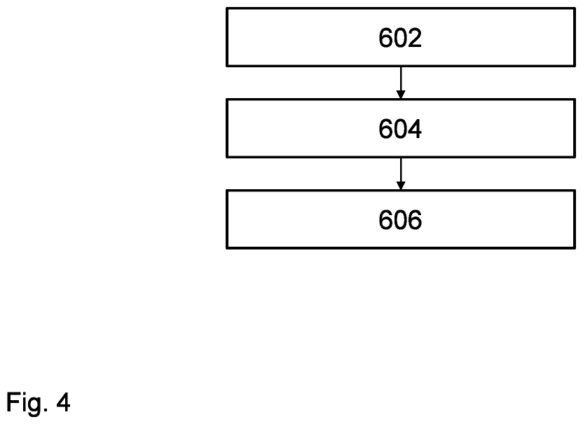

FIG. 4: a schematic method; and

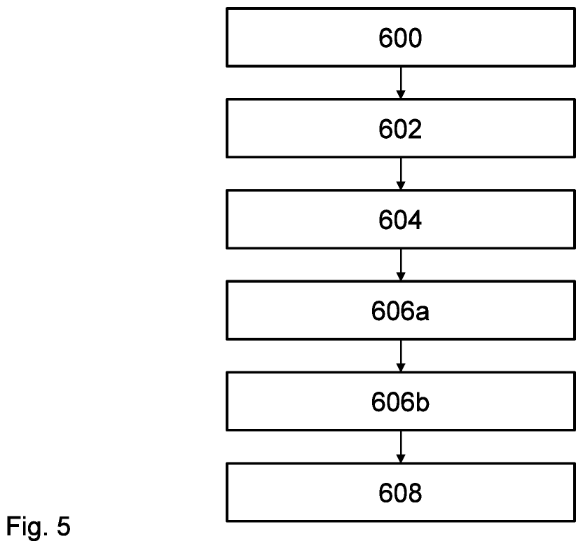

FIG. 5: a further schematic method.

In the figures, identical or essentially functionally identical or similar elements are designated by the same reference signs.

The circuit carrier 1 shown in FIG. 1 has a base body 2 and a total of nine conductor paths, two of which are exemplified by the reference signs 12, 18.

The base body 2 extends in the longitudinal direction L from a first end 4 to a second end 6. Orthogonal to the longitudinal direction L, the base body 2 extends in the width direction B and in the height direction H. The first conductor track 12 extends in the width direction B and in the height direction H, respectively.

The first conductor path 12 extends from a first conductor path end 14 toward a second conductor path end 16 in a longitudinal conductor path direction that is oriented parallel to the longitudinal direction L. The conductor paths 12, 18 are arranged parallel to each other.

The base body 2 is substantially made of a plastic material 8 and metal particles 10. The base body surface 3 is substantially free of metal particles 10. Therefore, a portion of the base body 2 is shown broken with a dashed line to visualize the interior of the base body. It is shown that the plastic material 8 is also present inside the base body 2. The base body surface 3 is essentially configured exclusively by the plastic material 8. However, the metal particles 10 are additionally present inside the base body 2.

The base body surface 3 of the base body 2 has been applied with a smoothing means dissolving the plastic material 8, so that the base body surface is substantially free of metal particles 10. The metal particles 10 may be, for example, copper particles which have preferably been added to the plastic material in the form of a copper powder.

The conductor paths 12, 18 were created by means of laser activation and metallization. For this purpose, the areas of the base body 2 in which the conductor paths are to be arranged, the so-called conductor path sections, were activated by means of a laser. Metallic nuclei were generated by means of a physical and/or physicochemical reaction. The activated conductor path sections were then metallized with a conductor path material, in particular copper.

FIG. 2 shows a detailed view of the base body 2. In particular, the adjacently arranged conductor paths 12, 18 are shown. A conductor path-free area is provided between the conductor paths 12, 18, so that the plastic material 8 is shown here. The same applies to the respective outer areas adjacent to the conductor path 12 and the conductor path 18.

FIG. 3 shows a base body 20 with conductor paths 24, 26 produced by an additive manufacturing process, the base body 20 also being made of a plastic material 22 with metal particles. However, the base body 20 has not been applied with a smoothing means that dissolves the plastic material 8, so the base body surface is not free of metal particles.

Since the base body surface of the base body 20 was not free of metal particles, a plurality of impurity metallizations 28 occurred during metallization. These impurity metallizations 28 have similar characteristics to the conductor paths 24, 26. The foreign metallizations 28 lead to an increased risk of short circuits between the conductor paths 24, 26. In addition, the quality of the circuit carrier comprising the base body 20 is impaired. This shows the great advantage of applying the smoothing means which dissolves the plastic material 8 to the base body 2, namely that the foreign metallizations 28 are essentially avoided.

FIG. 4 shows a schematic method. In step 602, a base body 2 is produced using an additive manufacturing process, the base body 2 comprising a plastic material 8 with metal particles 10. In step 604, the base body surface 3 of the base body 2 is applied with a smoothing means dissolving the plastic material 8, such that the base body surface 3 is substantially free of metal particles 10. In step 606, at least one conductor path 12, 18 is generated on the base body surface 3.

FIG. 5 shows a preferred embodiment of the method. In step 600, a CAD design of the circuit carrier 1 is created. Here, in particular, the three-dimensional structure of the base body 2, as well as the positioning and the course of the conductor paths are provided. Steps 602 and 604 are configured in the same way as the method described in FIG. 4 above.

Step 606 is divided into two sub steps. In step 606a, the conductor path sections on the base body surface in which the conductor paths 12, 18 are to be arranged are laser-activated. In step 606b, these conductor path sections are metallized with a conductor path material. As a result, the conductor path material adheres to the conductor path sections and the conductor paths are thus configured. In step 608, various circuit components are arranged on the circuit substrate 1 so that a circuit is configured.

By means of the method described in the foregoing, a higher quality circuit carrier 1 is made possible. In particular, the conductor paths 12, 18 can be configured with a smaller width. Furthermore, the conductor paths 12, 18 can be arranged with a smaller distance between each other, since the risk of a short circuit is reduced, since foreign metallizations 28 are avoided. As a result, a higher quality circuit carrier 1 is provided.

This circuit carrier 1 can furthermore have a smaller size, so that the method described in the foregoing contributes to the miniaturization of products, for example cell phones, headphones and the like. Furthermore, the freedoms gained with respect to the circuit carrier geometry enable lightweight construction, resulting in a circuit carrier 1 with a lower weight. Furthermore, it is made possible that a higher degree of functional integration is realized in this more compact and lighter circuit carrier 1.

### REFERENCE SIGNS

1 Circuit carrier
2 Base body
3 Base body surface
4 First end
6 Second end
8 Plastic material
10 Metal particles
12 First conductor path
14 First conductor path end
16 Second conductor path end
18 Second conductor path
20 Base body without smoothing
22 Plastic material
24 Conductor path
26 Conductor path
28 Foreign metallization
L Longitudinal direction
B Width direction
H Height direction

1. Method of manufacturing a circuit carrier for electronic and/or mechatronic components, comprising the steps:
Producing a base body using an additive manufacturing method, the base body comprising a plastic material with metal particles,
Applying a smoothing agent dissolving the plastic material to a base body surface of the base body so that the base body surface is substantially free of the metal particles, and
producing at least one conductor path on the base body surface.

2. Method according to claim 1, wherein applying the smoothing agent dissolving the plastic material to the base body surface is performed such that the base body surface has an average roughness depth of less than 50 μm, less than 40 μm, less than 30 μm, and/or less than 20 μm.

3. Method according to claim 1, wherein the additive manufacturing method comprises a selective laser melting process, an absorption printing process, and/or a fused layer process.

4. Method according to claim 1, wherein producing the at least one conductor path comprises the step of:
Laser activating one, two or more conductor path sections on the base body surface in which one, two or more conductor paths are to be arranged.

5. Method according to claim 4, wherein producing the at least one conductor path comprises the step of:
Metallizing the conductor path sections with a conductor path material forming the conductor path or conductor paths.

6. Method according to claim 1, wherein the applying comprises steaming with the smoothing agent at a predetermined steaming pressure and/or temperature.

7. Method according to claim 6, wherein
the steaming pressure is between 0-1 bar, and/or
the predetermined temperature is between 100° C.-120° C.

8. Method according to claim 1, wherein the smoothing agent comprises:
an etchant comprising formic acid, and/or
an alcohol comprising benzyl alcohol.

9. Method according to claim 1, wherein
the metal particles comprise copper particles, and/or
the metal particles comprise copper particles that have a particle size of less than 30 μm, less than 20 μm, or between 5 μm and 15 μm.

10. Method according to claim 1, wherein the plastic material:
is a thermoplastic material, or
is polyamide and/or thermoplastic polyurethane.

11. Circuit carrier for electronic and/or mechatronic components produced by the method according to claim 1, comprising
a base body produced by an additive manufacturing process comprising a plastic material with metal particles,
the base body having a base body surface substantially free of metal particles, and
at least one conductor path.

12. Circuit carrier according to claim 11, wherein the base body surface has an averaged roughness depth of less than 50 μm, less than 40 μm, less than 30 μm, and/or less than 20 μm.

13. Circuit carrier according to claim 11, wherein
the metal particles comprise copper particles, and/or
the metal particles comprise copper particles that have a particle size of less than 30 μm, less than 20 μm, or between 5 μm and 15 μm.

14. Circuit carrier according to claim 11, wherein the plastic material:
Is configured a thermoplastic material, or
is polyamide and/or thermoplastic polyurethane.

15. Circuit comprising the circuit carrier according to claim 11 and at least one circuit component.
